(19) United States
(12) Patent Application Publication
(10) Pub. No.: US 2024/0421247 A1
(43) Pub. Date: Dec. 19, 2024

(54) DISPLAY DEVICE USING LIGHT-EMITTING ELEMENT, AND MANUFACTURING METHOD THEREFOR

(71) Applicant: LG ELECTRONICS INC., Seoul (KR)

(72) Inventors: Kyoungtae WI, Seoul (KR); Byungjoon RHEE, Seoul (KR)

(73) Assignee: LG ELECTRONICS INC., Seoul (KR)

(21) Appl. No.: 18/706,613

(22) PCT Filed: Nov. 18, 2021
(86) PCT No.: PCT/KR2021/017025

§ 371 Date: May 1, 2024

(51) Int. Cl. H01L 33/00; H01L 25/075; H01L 33/56; H01L 33/62

(52) U.S. Cl. CPC H01L 33/0095; H01L 25/0753; H01L 33/56; H01L 33/62; H01L 2933/005

(57) ABSTRACT

The present disclosure is applicable to a technical field related to a display device, and relates to: a display device using, for example, a micro light-emitting diode (LED); and a manufacturing method therefor. In order to accomplish the described objective, the present disclosure may comprise the steps of: preparing a growth substrate having light-emitting elements; preparing a wiring substrate having wiring electrodes; forming a first adhesive pattern on a first wiring electrode from among the wiring electrodes and/or a first light-emitting element from among the light-emitting elements; transferring the first light-emitting element onto the first wiring electrode so that the first light-emitting element from among the light-emitting elements is adhered to the first wiring electrode by means of the first adhesive pattern; forming, on a second wiring electrode adjacent to the first wiring electrode from among the wiring electrodes and/or a second light-emitting element adjacent to the first light-emitting element from among the light-emitting elements, a second adhesive pattern having a height that differs from the height of the first adhesive pattern; and transferring the second light-emitting element onto the second wiring electrode so that the second light-emitting element from among the light-emitting elements is adhered to the second wiring electrode by means of the second adhesive pattern.

### TECHNICAL FIELD

The present disclosure is applicable to a field of display device technology and relates, for example, to a display device using micro light emitting diodes (LEDs) and method for manufacturing the same.

### BACKGROUND

Recently, display devices with excellent characteristics such as thinness and flexibility have been developed in the field of display technology. In contrast, currently commercialized main displays are represented by liquid crystal displays (LCDs) and active matrix organic light emitting diodes (AMOLEDs).

Light emitting diodes (LEDs) are well-known semiconductor light emitting devices that convert electricity into light. The LEDs have been used as light sources for display images in electronic devices including information communication devices, along with gallium phosphide nitride (GaP:N)-based green LEDs, starting from the commercialization of red LEDs using gallium arsenide phosphide (GaAsP) compound semiconductors in 1962. Thus, it is possible to implement a flexible display based on the semiconductor light emitting device, thereby offering solutions to the aforementioned issues.

Recently, LEDs have been increasingly miniaturized and manufactured into micro LEDs, which are utilized as pixels in display devices. The micro LEDs are transferred onto substrates in various ways.

As the conventional method for transferring micro LEDs, a method of separating micro LEDs from LED wafers using a donor such as polydimethylsiloxane (PDMS) and then transferring the micro LEDs onto a wiring substrate. This method allows to selectively transfer micro LEDs from densely packed LED wafers.

In particular, for full-color implementation, individual transfers from three types of LED wafers for red (R), blue (B), and green (G) LEDs are required. Therefore, a method of transferring R, G, and B LEDs individually based on the donor and then re-transferring the LEDs to a wiring substrate is mainly proposed.

When a donor such as PDMS is applied, it is possible to obtain good LED transfer properties through a Laser Lift-Off (LLO) process due to low elasticity and free deformation. However, due to the flexible nature, it is susceptible to stretching or shrinking, and due to inadequate positional accuracy, there are challenges in applying the method to ultra-small micro LEDs and high-resolution devices.

Therefore, when a donor is applied, a minimum of two transfers are required, including a transfer from an LED wafer to the donor (primary transfer) and from the donor to a wiring substrate (secondary transfer). For RGB transferring, a minimum of four transfers are required.

As a result, transfer methods without the use of donors are being developed due to an increase in the positional accuracy errors and cost associated with an increase in the frequency of transfers.

Thus, there is a demand for methods enabling a direct transfer from an LED wafer to a wiring substrate. However, even in such cases, there are challenges in implementing full-color displays due to interference caused by previously transferred LEDs during individual RGB transfers.

### DISCLOSURE

### Technical Problem

The present disclosure aims to provide a display device based on light emitting devices capable of being directly transferred from a light emitting device wafer to a wiring substrate and method for manufacturing the same.

In addition, the present disclosure aims to provide a display device capable of reducing the frequency of transfers required to electrically connect light emitting devices and wiring electrodes and method for manufacturing the same.

Furthermore, the present disclosure aims to provide a display device capable of preventing interference caused by previously transferred light emitting devices when the light emitting devices are individually transferred from three types of wafers: red (R), blue (B), and green (G), to a wiring substrate and method for manufacturing the same.

### Technical Solution

In an aspect of the present disclosure, provided herein is a method including: preparing a growth substrate on which light emitting devices are formed: preparing a wiring substrate provided with wiring electrodes; forming a first adhesive pattern on at least one of a first wiring electrode among the wiring electrodes and a first light emitting device among the light emitting devices; transferring the first light emitting device onto the first wiring electrode such that the first light emitting device among the light emitting devices is adhered to the first wiring electrode by the first adhesive pattern; forming a second adhesive pattern on at least one of a second wiring electrode adjacent to the first wiring electrode among the wiring electrodes and a second light emitting device adjacent to the first light emitting device among the light emitting devices, wherein a height of the first adhesive pattern is different from a height of the second adhesive pattern; and transferring the second light emitting device onto the second wiring electrode such that the second light emitting device among the light emitting devices is adhered to the second wiring electrode by the second adhesive pattern.

In an exemplary embodiment, each of the first and second adhesive patterns may have adhesive properties for adhering the wiring electrodes to the light emitting devices and transfer properties required for transferring the light emitting devices onto the wiring electrodes.

In an exemplary embodiment, the height of the second adhesive pattern may be greater than the height of the first adhesive pattern.

In an exemplary embodiment, the method may further include: forming a third adhesive pattern on at least one of a third wiring electrode adjacent to the second wiring electrode among the wiring electrodes and a third light emitting device adjacent to the second light emitting device among the light emitting devices, wherein a height of the second adhesive pattern is different from a height of the third adhesive pattern; and transferring the third light emitting device onto the third wiring electrode such that the third light emitting device among the light emitting devices is adhered to the third wiring electrode by the third adhesive pattern.

In an exemplary embodiment, the height of the third adhesive pattern may be greater than the height of the second adhesive pattern.

In an exemplary embodiment, forming the first and second adhesive patterns may include performing dispensing, pattern printing, or inkjet printing of adhesive materials onto the wiring substrate.

In an exemplary embodiment, the method may further include transitioning states of the first and second adhesive patterns to a semi-solid state.

In an exemplary embodiment, transitioning the states of the first and second adhesive patterns to the semi-solid state may include an ultraviolet (UV) semi-curing (UV B-stage) process.

In an exemplary embodiment, the method may further include performing Laser Lift-Off (LLO) on the growth substrate after transitioning the states of the adhesive patterns to the semi-solid state.

In an exemplary embodiment, the method may further include performing thermal compression bonding on the first and second light emitting devices simultaneously.

In an exemplary embodiment, performing the thermal compression bonding may include applying pressure such that the first and second adhesive patterns with different heights have a same height.

In an exemplary embodiment, each of the first and second adhesive patterns is made of a non-conductive paste (NCP) capable of a state transition to a semi-solid state.

In an exemplary embodiment, the NCP may include a UV B-Stage composition and a thermosetting composition.

In an exemplary embodiment, a content of the UV B-Stage composition in the NCP may range from 20% to 50%.

In an exemplary embodiment, a viscosity of the NCP may range from 10,000 to 100,000 centipoise (cps).

In an exemplary embodiment, the NCP may include at least one of an acrylate and an epoxy acrylate.

In an exemplary embodiment, a curvature of an adhesive pattern corresponding to bonding pairs constituting one pixel among bonding pairs may be constant.

In another aspect of the present disclosure, provided herein a device including: a wiring substrate; wiring electrodes positioned on the wiring substrate and including a first wiring electrode, a second wiring electrode, and a third wiring electrode that form a unit pixel: light emitting devices including a first light emitting device, a second light emitting device, and a third light emitting device respectively and electrically connected to the first wiring electrode, the second wiring electrode, and the third wiring electrode that form the unit pixel; and adhesive patterns including a first adhesive pattern, a second adhesive pattern, and a third adhesive pattern formed independently of each other and having adhesive properties for respectively adhering the first wiring electrode to the first light emitting device, the second wiring electrode to the second light emitting device, and the third wiring electrode to the third light emitting device and transfer properties required for transferring the light emitting devices to the wiring electrodes.

In an exemplary embodiment, after thermal compression bonding, the first adhesive pattern, the second adhesive pattern, and the third adhesive pattern with different heights may have a same height.

In an exemplary embodiment, each of the first adhesive pattern, the second adhesive pattern, and the third adhesive pattern may be made of an NCP capable of a state transition to a semi-solid state, and the NCP may include a UV B-Stage composition and a thermosetting composition.

### Advantageous Effects

According to a display device and method for manufacturing the same in accordance with embodiments of the present disclosure, when electrically connecting the electrodes of a light emitting device to wiring electrodes, the light emitting device may be directly transferred from a wafer (growth substrate) to a wiring substrate using an adhesive pattern having both adhesive and transfer properties, thereby enabling process simplification, cost reduction, and mass production based on a decrease in the frequency of transfers.

According to a display device and method for manufacturing the same in accordance with embodiments of the present disclosure, a process of transferring a light emitting device from a wafer to a temporary substrate may be omitted, thereby improving yield and preventing issues related to the movement of the light emitting device, which may occur during the corresponding transfer process.

According to a display device and method for manufacturing the same in accordance with embodiments of the present disclosure, an adhesive pattern may sufficiently encapsulate light emitting devices, thereby mitigating the impact on the light emitting devices when the light emitting devices are detached from a wafer.

According to a display device and method for manufacturing the same in accordance with embodiments of the present disclosure, an adhesive pattern for one or more light emitting devices may be provided separately from an adhesive pattern for other light emitting devices, and thus sufficient fluid space for adhesives may be secured, thereby maintain uniform characteristics even for large-area processes. For instance, gap filling properties and constant bonding thickness (planarization) may be achieved.

According to a display device and method for manufacturing the same in accordance with embodiments of the present disclosure, after individually transferring light emitting devices representing different colors, bonding may be simultaneously performed thereon, thereby preventing illumination defects caused by interference and collision, where initially bonded light emitting device are affected by a subsequently conducted bonding process when bonding processes are separately performed for light emitting devices with different colors.

According to a display device and method for manufacturing the same in accordance with embodiments of the present disclosure, adhesive patterns may have different heights during a transfer process by differentiating the coating thickness of each adhesive pattern, thereby preventing transfer failure due to interference.

### BRIEF DESCRIPTION OF THE DRAWINGS

FIG. 1 is a conceptual view illustrating an exemplary display device based on semiconductor light emitting devices according to the present disclosure.

FIG. 2 is a partially enlarged view of portion A of FIG. 1.

FIGS. 3A and 3B are cross-sectional views taken along lines B-B and C-C of FIG. 2.

FIG. 4 is a conceptual view illustrating a flip-chip type semiconductor light emitting device of FIG. 3.

FIG. 5A to 5C are conceptual views illustrating various examples of color implementation in a flip-chip type semiconductor light emitting device.

FIG. 6 is cross-sectional views for explaining a method of manufacturing a display device based on semiconductor light emitting devices according to the present disclosure.

FIG. 7 is a perspective view illustrating another exemplary display device based on semiconductor light emitting devices according to the present disclosure.

FIG. 8 is a cross-sectional view taken along line D-D of FIG. 7.

FIG. 9 is a conceptual view illustrating a vertical semiconductor of FIG. 8;

FIGS. 10 and 11 are views illustrating display devices according to embodiments of the present disclosure.

FIGS. 12 and 13 illustrate adhesive patterns according to embodiments of the present disclosure.

FIG. 14 is a flowchart illustrating a method of manufacturing a display device based on light emitting devices according to an embodiment of the present disclosure.

FIGS. 15 to 24 are cross-sectional views illustrating steps of the method of manufacturing a display device based on light emitting devices according to an embodiment of the present disclosure.

### DETAILED DESCRIPTION

Reference will now be made in detail to embodiments of the present disclosure, examples of which are illustrated in the accompanying drawings. Wherever possible, the same reference numbers will be used throughout the drawings to refer to the same or like parts, and a redundant description thereof will be omitted. As used herein, the suffixes “module” and “unit” are added or used interchangeably to facilitate preparation of this specification, and are not intended to suggest distinct meanings or functions. In describing embodiments disclosed in this specification, relevant well-known technologies may not be described in detail in order to avoid obscuring the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining two or more drawings are also within the scope of the present disclosure.

In addition, when an element such as a layer, a region, or a substrate is described as being “on” another element, it is to be understood that the element may be directly on the other element, or there may be an intermediate element between them.

The display device described herein conceptually includes all display devices that display information with a unit pixel or a set of unit pixels. Therefore, the term “display device” may be applied not only to finished products but also to parts. For example, a panel corresponding to a part of a digital TV also independently corresponds to the display device in the present specification. Such finished products include a mobile phone, a smartphone, a laptop computer, a digital broadcasting terminal, a personal digital assistant (PDA), a portable multimedia player (PMP), a navigation system, a slate PC, a tablet PC, an Ultrabook, a digital TV, a desktop computer, and the like.

However, it will be readily apparent to those skilled in the art that the configuration according to the embodiments described herein is also applicable to new products to be developed later as display devices.

In addition, the term “semiconductor light-emitting element” mentioned in this specification conceptually includes an LED, a micro LED, and the like, and may be used interchangeably therewith.

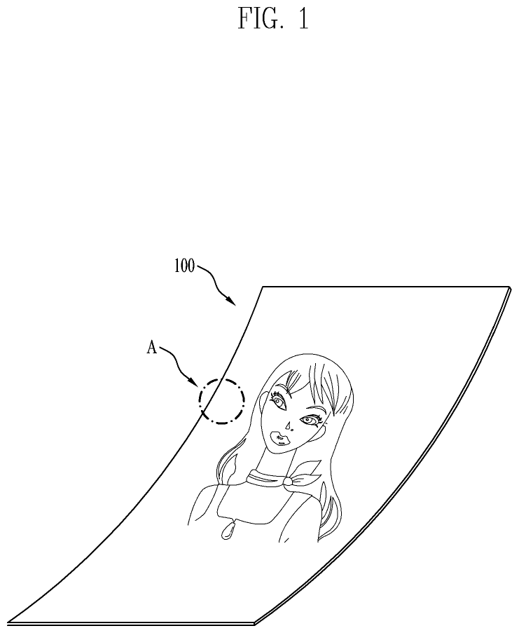

FIG. 1 is a conceptual view illustrating an embodiment of a display device using a semiconductor light emitting element according to the present disclosure.

As shown in FIG. 1, information processed by a controller (not shown) of a display device 100 may be displayed using a flexible display.

The flexible display may include, for example, a display that can be warped, bent, twisted, folded, or rolled by external force.

Furthermore, the flexible display may be, for example, a display manufactured on a thin and flexible substrate that can be warped, bent, folded, or rolled like paper while maintaining the display characteristics of a conventional flat panel display.

When the flexible display remains in an unbent state (e.g., a state having an infinite radius of curvature) (hereinafter referred to as a first state), the display area of the flexible display forms a flat surface. When the display in the first sate is changed to a bent state (e.g., a state having a finite radius of curvature) (hereinafter referred to as a second state) by external force, the display area may be a curved surface. As shown in FIG. 1, the information displayed in the second state may be visual information output on a curved surface. Such visual information may be implemented by independently controlling the light emission of subpixels arranged in a matrix form. The unit pixel may mean, for example, a minimum unit for implementing one color.

The unit pixel of the flexible display may be implemented by a semiconductor light emitting element. In the present disclosure, a light emitting diode (LED) is exemplified as a type of the semiconductor light emitting element configured to convert electric current into light. The LED may be formed in a small size, and may thus serve as a unit pixel even in the second state.

Hereinafter, a flexible display implemented using the LED will be described in more detail with reference to the drawings.

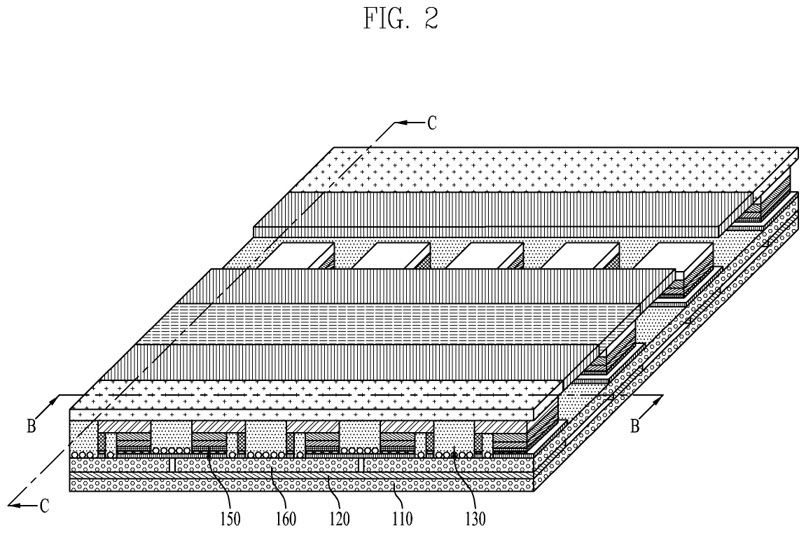

FIG. 2 is a partially enlarged view showing part A of FIG. 1.

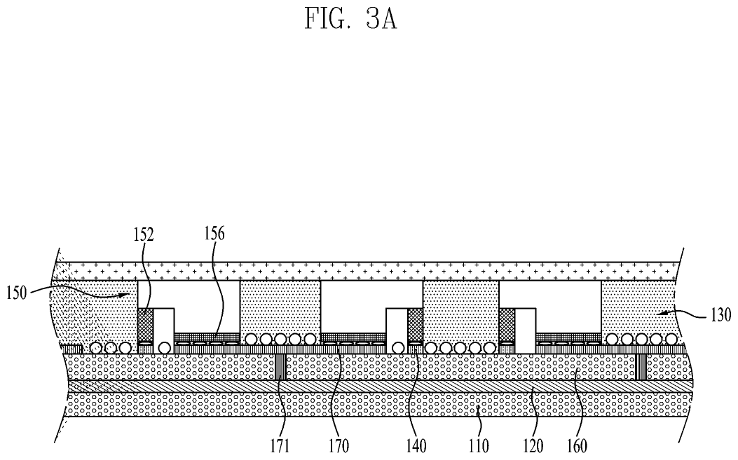

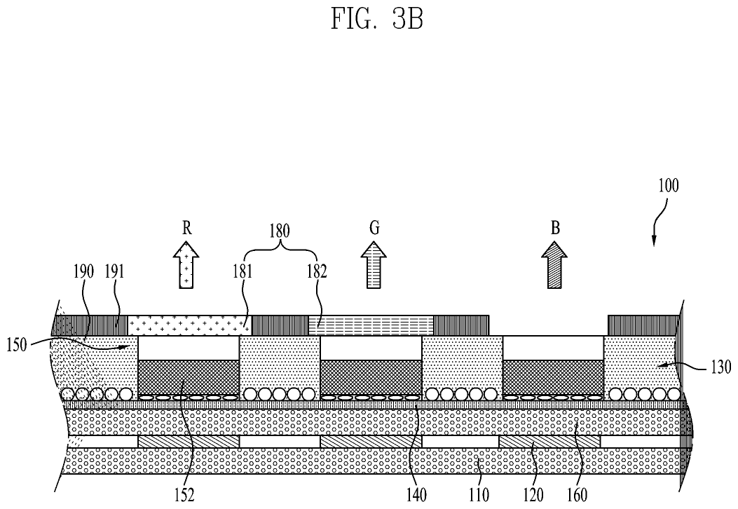

FIGS. 3A and 3B are cross-sectional views taken along lines B-B and C-C in FIG. 2.

As shown in FIGS. 2, 3A and 3B, the display device 100 using a passive matrix (PM) type semiconductor light emitting element is exemplified as the display device 100 using a semiconductor light emitting element. However, the examples described below are also applicable to an active matrix (AM) type semiconductor light emitting element.

The display device 100 may include a substrate 110, a first electrode 120, a conductive adhesive layer 130, a second electrode 140, and at least one semiconductor light emitting element 150, as shown in FIG. 2.

The substrate 110 may be a flexible substrate. For example, to implement a flexible display device, the substrate 110 may include glass or polyimide (PI). Any insulative and flexible material such as polyethylene naphthalate (PEN) or polyethylene terephthalate (PET) may be employed. In addition, the substrate 110 may be formed of either a transparent material or an opaque material.

The substrate 110 may be a wiring substrate on which the first electrode 120 is disposed. Thus, the first electrode 120 may be positioned on the substrate 110.

As shown in FIG. 3A, an insulating layer 160 may be disposed on the substrate 110 on which the first electrode 120 is positioned, and an auxiliary electrode 170 may be positioned on the insulating layer 160. In this case, a stack in which the insulating layer 160 is laminated on the substrate 110 may be a single wiring substrate. More specifically, the insulating layer 160 may be formed of an insulative and flexible material such as PI, PET, or PEN, and may be integrated with the substrate 110 to form a single substrate.

The auxiliary electrode 170, which is an electrode that electrically connects the first electrode 120 and the semiconductor light emitting element 150, is positioned on the insulating layer 160, and is disposed to correspond to the position of the first electrode 120. For example, the auxiliary electrode 170 may have a dot shape and may be electrically connected to the first electrode 120 by an electrode hole 171 formed through the insulating layer 160. The electrode hole 171 may be formed by filling a via hole with a conductive material.

As shown in FIG. 2 or 3A, a conductive adhesive layer 130 may be formed on one surface of the insulating layer 160, but embodiments of the present disclosure are not limited thereto. For example, a layer performing a specific function may be formed between the insulating layer 160 and the conductive adhesive layer 130, or the conductive adhesive layer 130 may be disposed on the substrate 110 without the insulating layer 160. In a structure in which the conductive adhesive layer 130 is disposed on the substrate 110, the conductive adhesive layer 130 may serve as an insulating layer.

The conductive adhesive layer 130 may be a layer having adhesiveness and conductivity. For this purpose, a material having conductivity and a material having adhesiveness may be mixed in the conductive adhesive layer 130. In addition, the conductive adhesive layer 130 may have ductility, thereby providing making the display device flexible.

As an example, the conductive adhesive layer 130 may be an anisotropic conductive film (ACF), an anisotropic conductive paste, a solution containing conductive particles, or the like. The conductive adhesive layer 130 may be configured as a layer that allows electrical interconnection in the direction of the Z-axis extending through the thickness, but is electrically insulative in the horizontal X-Y direction. Accordingly, the conductive adhesive layer 130 may be referred to as a Z-axis conductive layer (hereinafter, referred to simply as a “conductive adhesive layer”).

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

The ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

Referring back to FIG. 3A, the second electrode 140 is positioned on the insulating layer 160 and spaced apart from the auxiliary electrode 170. That is, the conductive adhesive layer 130 is disposed on the insulating layer 160 having the auxiliary electrode 170 and the second electrode 140 positioned thereon.

After the conductive adhesive layer 130 is formed with the auxiliary electrode 170 and the second electrode 140 positioned on the insulating layer 160, the semiconductor light emitting element 150 is connected thereto in a flip-chip form by applying heat and pressure. Thereby, the semiconductor light emitting element 150 is electrically connected to the first electrode 120 and the second electrode 140.

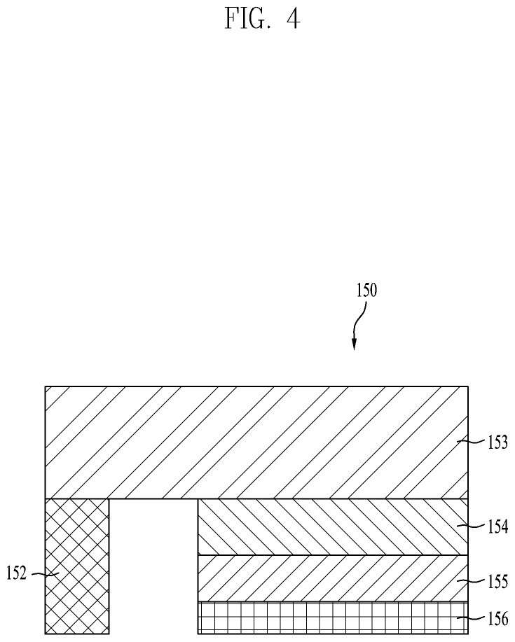

FIG. 4 is a conceptual view illustrating the flip-chip type semiconductor light emitting element of FIG. 3.

Referring to FIG. 4, the semiconductor light emitting element may be a flip chip-type light emitting device.

For example, the semiconductor light emitting element may include a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 disposed on the n-type semiconductor layer 153 and horizontally spaced apart from the p-type electrode 156. In this case, the p-type electrode 156 may be electrically connected to the auxiliary electrode 170, which is shown in FIG. 3, by the conductive adhesive layer 130, and the n-type electrode 152 may be electrically connected to the second electrode 140.

Referring back to FIGS. 2, 3A and 3B, the auxiliary electrode 170 may be elongated in one direction. Thus, one auxiliary electrode may be electrically connected to the plurality of semiconductor light emitting elements 150. For example, p-type electrodes of semiconductor light emitting elements on left and right sides of an auxiliary electrode may be electrically connected to one auxiliary electrode.

More specifically, the semiconductor light emitting element 150 may be press-fitted into the conductive adhesive layer 130 by heat and pressure. Thereby, only the portions of the semiconductor light emitting element 150 between the p-type electrode 156 and the auxiliary electrode 170 and between the n-type electrode 152 and the second electrode 140 may exhibit conductivity, and the other portions of the semiconductor light emitting element 150 do not exhibit conductivity as they are not press-fitted. In this way, the conductive adhesive layer 130 interconnects and electrically connects the semiconductor light emitting element 150 and the auxiliary electrode 170 and interconnects and electrically connects the semiconductor light emitting element 150 and the second electrode 140.

The plurality of semiconductor light emitting elements 150 may constitute a light emitting device array, and a phosphor conversion layer 180 may be formed on the light emitting device array.

The light emitting device array may include a plurality of semiconductor light emitting elements having different luminance values. Each semiconductor light emitting element 150 may constitute a unit pixel and may be electrically connected to the first electrode 120. For example, a plurality of first electrodes 120 may be provided, and the semiconductor light emitting elements may be arranged in, for example, several columns. The semiconductor light emitting elements in each column may be electrically connected to any one of the plurality of first electrodes.

In addition, since the semiconductor light emitting elements are connected in a flip-chip form, semiconductor light emitting elements grown on a transparent dielectric substrate may be used. The semiconductor light emitting elements may be, for example, nitride semiconductor light emitting elements. Since the semiconductor light emitting element 150 has excellent luminance, it may constitute an individual unit pixel even when it has a small size.

As shown in FIGS. 3A and 3B, a partition wall 190 may be formed between the semiconductor light emitting elements 150. In this case, the partition wall 190 may serve to separate individual unit pixels from each other, and may be integrated with the conductive adhesive layer 130. For example, by inserting the semiconductor light emitting element 150 into the ACF, the base member of the ACF may form the partition wall.

In addition, when the base member of the ACF is black, the partition wall 190 may have reflectance and increase contrast even without a separate black insulator.

As another example, a reflective partition wall may be separately provided as the partition wall 190. In this case, the partition wall 190 may include a black or white insulator depending on the purpose of the display device. When a partition wall including a white insulator is used, reflectivity may be increased. When a partition wall including a black insulator is used, it may have reflectance and increase contrast.

The phosphor conversion layer 180 may be positioned on the outer surface of the semiconductor light emitting element 150. For example, the semiconductor light emitting element 150 may be a blue semiconductor light emitting element that emits blue (B) light, and the phosphor conversion layer 180 may function to convert the blue (B) light into a color of a unit pixel. The phosphor conversion layer 180 may be a red phosphor 181 or a green phosphor 182 constituting an individual pixel.

That is, the red phosphor 181 capable of converting blue light into red (R) light may be laminated on a blue semiconductor light emitting element at a position of a unit pixel of red color, and the green phosphor 182 capable of converting blue light into green (G) light may be laminated on the blue semiconductor light emitting element at a position of a unit pixel of green color. Only the blue semiconductor light emitting element may be used alone in the portion constituting the unit pixel of blue color. In this case, unit pixels of red (R), green (G), and blue (B) may constitute one pixel. More specifically, a phosphor of one color may be laminated along each line of the first electrode 120. Accordingly, one line on the first electrode 120 may be an electrode for controlling one color. That is, red (R), green (G), and blue (B) may be sequentially disposed along the second electrode 140, thereby implementing a unit pixel.

However, embodiments of the present disclosure are not limited thereto. Unit pixels of red (R), green (G), and blue (B) may be implemented by combining the semiconductor light emitting element 150 and the quantum dot (QD) rather than using the phosphor.

Also, a black matrix 191 may be disposed between the phosphor conversion layers to improve contrast. That is, the black matrix 191 may improve contrast of light and darkness.

However, embodiments of the present disclosure are not limited thereto, and anther structure may be applied to implement blue, red, and green colors.

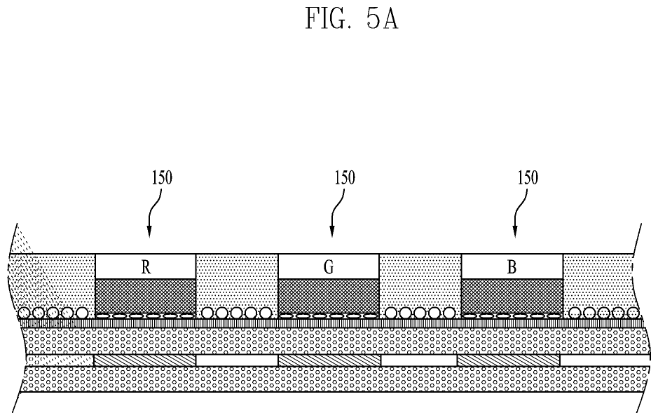

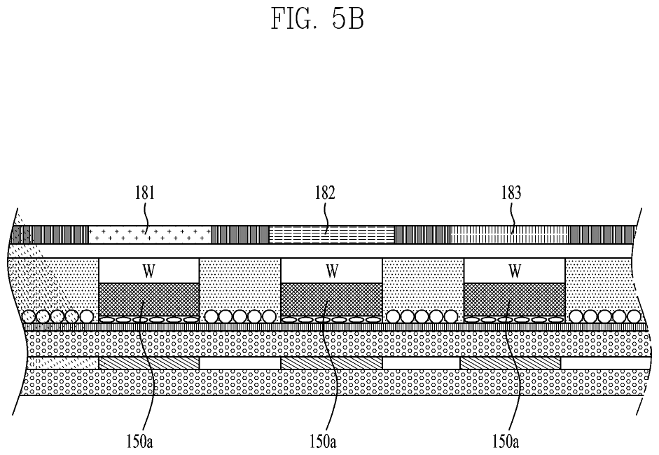

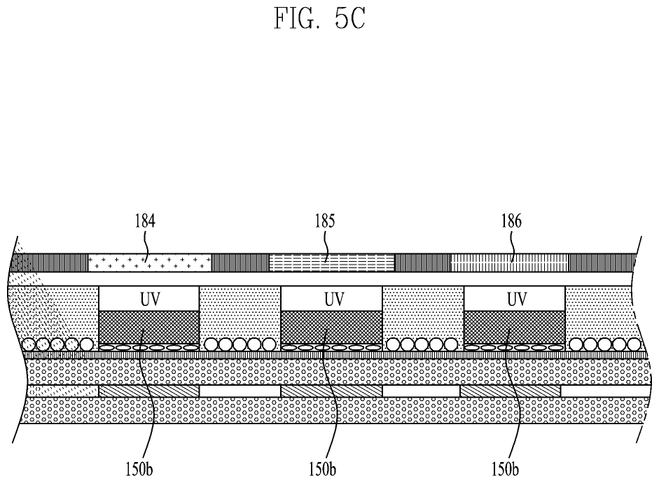

FIGS. 5A to 5C are conceptual views illustrating various examples of implementation of colors in relation to a flip-chip type semiconductor light emitting element.

Referring to FIG. 5A, each semiconductor light emitting element may be implemented as a high-power light emitting device emitting light of various colors including blue by using gallium nitride (GaN) as a main material and adding indium (In) and/or aluminum (Al).

In this case, each semiconductor light emitting element may be a red, green, or blue semiconductor light emitting element to form a unit pixel (subpixel). For example, red, green, and blue semiconductor light emitting elements R, G, and B may be alternately disposed, and unit pixels of red, green, and blue may constitute one pixel by the red, green and blue semiconductor light emitting elements. Thereby, a full-color display may be implemented.

Referring to FIG. 5B, the semiconductor light emitting element 150a may include a white light emitting device W having a yellow phosphor conversion layer, which is provided for each device. In this case, in order to form a unit pixel, a red phosphor conversion layer 181, a green phosphor conversion layer 182, and a blue phosphor conversion layer 183 may be disposed on the white light emitting device W. In addition, a unit pixel may be formed using a color filter repeating red, green, and blue on the white light emitting device W.

Referring to FIG. 5C, a red phosphor conversion layer 181, a green phosphor conversion layer 185, and a blue phosphor conversion layer 183 may be provided on a ultraviolet light emitting device. Not only visible light but also ultraviolet (UV) light may be used in the entire region of the semiconductor light emitting element. In an embodiment. UV may be used as an excitation source of the upper phosphor in the semiconductor light emitting element.

Referring back to this example, the semiconductor light emitting element is positioned on the conductive adhesive layer to constitute a unit pixel in the display device. Since the semiconductor light emitting element has excellent luminance, individual unit pixels may be configured despite even when the semiconductor light emitting element has a small size.

Regarding the size of such an individual semiconductor light emitting element, the length of each side of the device may be, for example, 80 μm or less, and the device may have a rectangular or square shape. When the semiconductor light emitting element has a rectangular shape, the size thereof may be less than or equal to 20 μm×80 μm.

In addition, even when a square semiconductor light emitting element having a side length of 10 μm is used as a unit pixel, sufficient brightness to form a display device may be obtained.

Therefore, for example, in case of a rectangular pixel having a unit pixel size of 600 μm×300 μm (i.e., one side by the other side), a distance of a semiconductor light emitting element becomes sufficiently long relatively.

Thus, in this case, it is able to implement a flexible display device having high image quality over HD image quality.

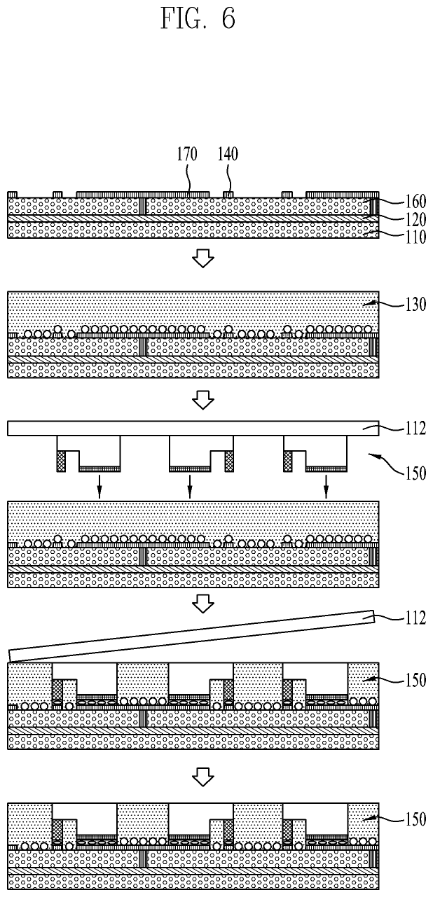

The above-described display device using the semiconductor light emitting element may be prepared by a new fabricating method. Such a fabricating method will be described with reference to FIG. 6 as follows.

FIG. 6 shows cross-sectional views of a method of fabricating a display device using a semiconductor light emitting element according to the present disclosure.

Referring to FIG. 6, first of all, a conductive adhesive layer 130 is formed on an insulating layer 160 located between an auxiliary electrode 170 and a second electrode 140. The insulating layer 160 is tacked on a wiring substrate 110. On the wiring substrate 110, a first electrode 120, the auxiliary electrode 170 and the second electrode 140 are disposed. In this case, the first electrode 120 and the second electrode 140 may be disposed in mutually orthogonal directions, respectively. In order to implement a flexible display device, the wiring substrate 110 and the insulating layer 160 may include glass or polyimide (PI) each.

For example, the conductive adhesive layer 130 may be implemented by an anisotropic conductive film. To this end, an anisotropic conductive film may be coated on the substrate on which the insulating layer 160 is located.

Subsequently, a temporary substrate 112, on which a plurality of semiconductor light emitting elements 150 configuring individual pixels are located to correspond to locations of the auxiliary electrode 170 and the second electrodes 140, is disposed in a manner that the semiconductor light emitting element 150 confronts the auxiliary electrode 170 and the second electrode 140).

In this regard, the temporary substrate 112 is a growing substrate for growing the semiconductor light emitting element 150 and may include a sapphire or silicon substrate.

The semiconductor light emitting element is configured to have a space and size for configuring a display device when formed in unit of wafer, thereby being effectively used for the display device.

Subsequently, the wiring substrate 110 and the temporary substrate 112 are thermally compressed together. By the thermocompression, the wiring substrate 110 and the temporary substrate 112 are bonded together. Owing to the property of an anisotropic conductive film having conductivity by thermocompression, only a portion among the semiconductor light emitting element 150, the auxiliary electrode 170) and the second electrode 140 has conductivity, via which the electrodes and the semiconductor light emitting element 150 may be connected electrically. In this case, the semiconductor light emitting element 150 is inserted into the anisotropic conductive film, by which a partition may be formed between the semiconductor light emitting elements 150.

Then the temporary substrate 112 is removed. For example, the temporary substrate 112 may be removed using Laser Lift-Off (LLO) or Chemical Lift-Off (CLO).

Finally, by removing the temporary substrate 112, the semiconductor light emitting elements 150 exposed externally. If necessary, the wiring substrate 110 to which the semiconductor light emitting elements 150 are coupled may be coated with silicon oxide (SiOx) or the like to form a transparent insulating layer (not shown).

In addition, a step of forming a phosphor layer on one side of the semiconductor light emitting element 150 may be further included. For example, the semiconductor light emitting element 150 may include a blue semiconductor light emitting element emitting Blue (B) light, and a red or green phosphor for converting the blue (B) light into a color of a unit pixel may form a layer on one side of the blue semiconductor light emitting element.

The above-described fabricating method or structure of the display device using the semiconductor light emitting element may be modified into various forms. For example, the above-described display device may employ a vertical semiconductor light emitting element.

Furthermore, a modification or embodiment described in the following may use the same or similar reference numbers for the same or similar configurations of the former example and the former description may apply thereto.

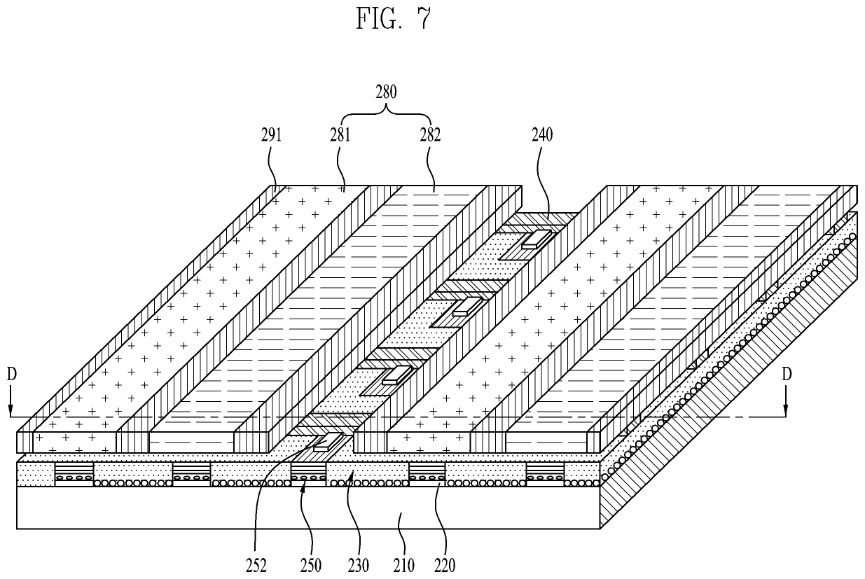

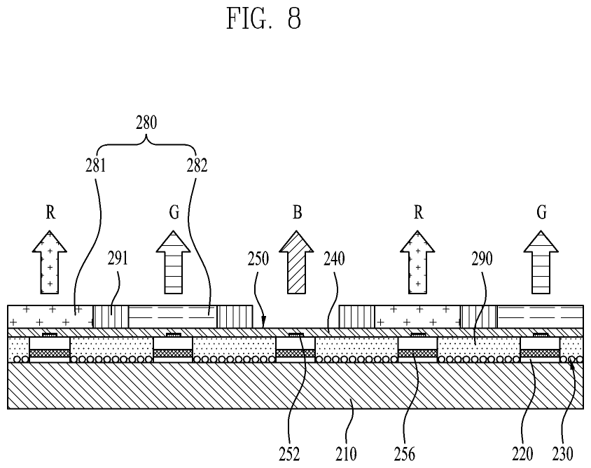

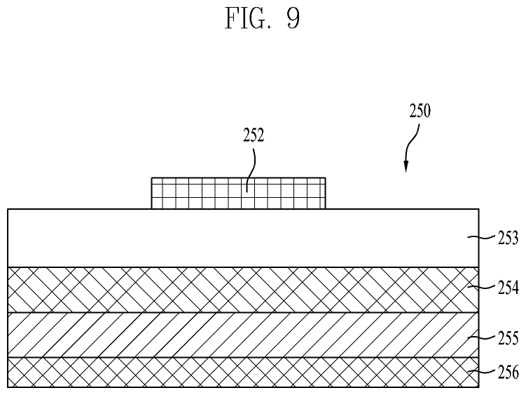

FIG. 7 is a perspective diagram of a display device using a semiconductor light emitting element according to another embodiment of the present disclosure, FIG. 8 is a cross-sectional diagram taken along a cutting line D-D shown in FIG. 8, and FIG. 9 is a conceptual diagram showing a vertical type semiconductor light emitting element shown in FIG. 8.

Referring to the present drawings, a display device may employ a vertical semiconductor light emitting device of a Passive Matrix (PM) type.

The display device includes a substrate 210, a first electrode 220, a conductive adhesive layer 230, a second electrode 240 and at least one semiconductor light emitting element 250.

The substrate 210 is a wiring substrate on which the first electrode 220 is disposed and may contain polyimide (PI) to implement a flexible display device. Besides, the substrate 210 may use any substance that is insulating and flexible.

The first electrode 210 is located on the substrate 210 and may be formed as a bar type electrode that is long in one direction. The first electrode 220 may be configured to play a role as a data electrode.

The conductive adhesive layer 230 is formed on the substrate 210 where the first electrode 220 is located. Like a display device to which a light emitting device of a flip chip type is applied, the conductive adhesive layer 230 may include one of an Anisotropic Conductive Film (ACF), an anisotropic conductive paste, a conductive particle contained solution and the like. Yet, in the present embodiment, a case of implementing the conductive adhesive layer 230 with the anisotropic conductive film is exemplified.

After the conductive adhesive layer has been placed in the state that the first electrode 220 is located on the substrate 210, if the semiconductor light emitting element 250 is connected by applying heat and pressure thereto, the semiconductor light emitting element 250 is electrically connected to the first electrode 220. In doing so, the semiconductor light emitting element 250 is preferably disposed to be located on the first electrode 220.

If heat and pressure is applied to an anisotropic conductive film, as described above, since the anisotropic conductive film has conductivity partially in a thickness direction, the electrical connection is established. Therefore, the anisotropic conductive film is partitioned into a conductive portion and a non-conductive portion.

Furthermore, since the anisotropic conductive film contains an adhesive component, the conductive adhesive layer 230 implements mechanical coupling between the semiconductor light emitting element 250 and the first electrode 220 as well as mechanical connection.

Thus, the semiconductor light emitting element 250 is located on the conductive adhesive layer 230, via which an individual pixel is configured in the display device. As the semiconductor light emitting element 250 has excellent luminance, an individual unit pixel may be configured in small size as well. Regarding a size of the individual semiconductor light emitting element 250, a length of one side may be equal to or smaller than 80 μm for example and the individual semiconductor light emitting element 250 may include a rectangular or square element. For example, the rectangular element may have a size equal to or smaller than 20 μm×80 μm.

The semiconductor light emitting element 250 may have a vertical structure.

Among the vertical type semiconductor light emitting elements, a plurality of second electrodes 240 respectively and electrically connected to the vertical type semiconductor light emitting elements 250 are located in a manner of being disposed in a direction crossing with a length direction of the first electrode 220.

Referring to FIG. 9, the vertical type semiconductor light emitting element 250 includes a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on then-type semiconductor layer 253. In this case, the p-type electrode 256 located on a bottom side may be electrically connected to the first electrode 220 by the conductive adhesive layer 230, and the n-type electrode 252 located on a top side may be electrically connected to a second electrode 240 described later. Since such a vertical type semiconductor light emitting element 250 can dispose the electrodes at top and bottom, it is considerably advantageous in reducing a chip size.

Referring to FIG. 8 again, a phosphor layer 280 may formed on one side of the semiconductor light emitting element 250. For example, the semiconductor light emitting element 250 may include a blue semiconductor light emitting element 251 emitting blue (B) light, and a phosphor layer 280 for converting the blue (B) light into a color of a unit pixel may be provided. In this regard, the phosphor layer 280 may include a red phosphor 281 and a green phosphor 282 configuring an individual pixel.

Namely, at a location of configuring a red unit pixel, the red phosphor 281 capable of converting blue light into red (R) light may be stacked on a blue semiconductor light emitting element. At a location of configuring a green unit pixel, the green phosphor 282 capable of converting blue light into green (G) light may be stacked on the blue semiconductor light emitting element. Moreover, the blue semiconductor light emitting element may be singly usable for a portion that configures a blue unit pixel. In this case, the unit pixels of red (R), green (G) and blue (B) may configure a single pixel.

Yet, the present disclosure is non-limited by the above description. In a display device to which a light emitting element of a flip chip type is applied, as described above, a different structure for implementing blue, red and green may be applicable.

Regarding the present embodiment again, the second electrode 240 is located between the semiconductor light emitting elements 250 and connected to the semiconductor light emitting elements electrically. For example, the semiconductor light emitting elements 250 are disposed in a plurality of columns, and the second electrode 240) may be located between the columns of the semiconductor light emitting elements 250.

Since a distance between the semiconductor light emitting elements 250 configuring the individual pixel is sufficiently long, the second electrode 240 may be located between the semiconductor light emitting elements 250.

The second electrode 240 may be formed as an electrode of a bar type that is long in one direction and disposed in a direction vertical to the first electrode.

In addition, the second electrode 240) and the semiconductor light emitting element 250) may be electrically connected to each other by a connecting electrode protruding from the second electrode 240). Particularly, the connecting electrode may include a n-type electrode of the semiconductor light emitting element 250. For example, the n-type electrode is formed as an ohmic electrode for ohmic contact, and the second electrode covers at least one portion of the ohmic electrode by printing or deposition. Thus, the second electrode 240 and the n-type electrode of the semiconductor light emitting element 250 may be electrically connected to each other.

Referring to FIG. 8 again, the second electrode 240 may be located on the conductive adhesive layer 230. In some cases, a transparent insulating layer (not shown) containing silicon oxide (SiOx) and the like may be formed on the substrate 210 having the semiconductor light emitting element 250 formed thereon. If the second electrode 240 is placed after the transparent insulating layer has been formed, the second electrode 240 is located on the transparent insulating layer. Alternatively, the second electrode 240 may be formed in a manner of being spaced apart from the conductive adhesive layer 230 or the transparent insulating layer.

If a transparent electrode of Indium Tin Oxide (ITO) or the like is sued to place the second electrode 240 on the semiconductor light emitting element 250, there is a problem that ITO substance has poor adhesiveness to an n-type semiconductor layer. Therefore, according to the present disclosure, as the second electrode 240 is placed between the semiconductor light emitting elements 250, it is advantageous in that a transparent electrode of ITO is not used. Thus, light extraction efficiency can be improved using a conductive substance having good adhesiveness to an n-type semiconductor layer as a horizontal electrode without restriction on transparent substance selection.

Referring to FIG. 8 again, a partition 290 may be located between the semiconductor light emitting elements 250. Namely, in order to isolate the semiconductor light emitting element 250 configuring the individual pixel, the partition 290 may be disposed between the vertical type semiconductor light emitting elements 250. In this case, the partition 290 may play a role in separating the individual unit pixels from each other and be formed with the conductive adhesive layer 230 as an integral part. For example, by inserting the semiconductor light emitting element 250 in an anisotropic conductive film, a base member of the anisotropic conductive film may form the partition.

In addition, if the base member of the anisotropic conductive film is black, the partition 290 may have reflective property as well as a contrast ratio may be increased, without a separate block insulator.

For another example, a reflective partition may be separately provided as the partition 290. The partition 290 may include a black or white insulator depending on the purpose of the display device.

In case that the second electrode 240 is located right onto the conductive adhesive layer 230 between the semiconductor light emitting elements 250, the partition 290 may be located between the vertical type semiconductor light emitting element 250 and the second electrode 240 each. Therefore, an individual unit pixel may be configured using the semiconductor light emitting element 250. Since a distance between the semiconductor light emitting elements 250 is sufficiently long, the second electrode 240 can be placed between the semiconductor light emitting elements 250. And, it may bring an effect of implementing a flexible display device having HD image quality.

In addition, as shown in FIG. 8, a black matrix 291 may be disposed between the respective phosphors for the contrast ratio improvement. Namely, the black matrix 291 may improve the contrast between light and shade.

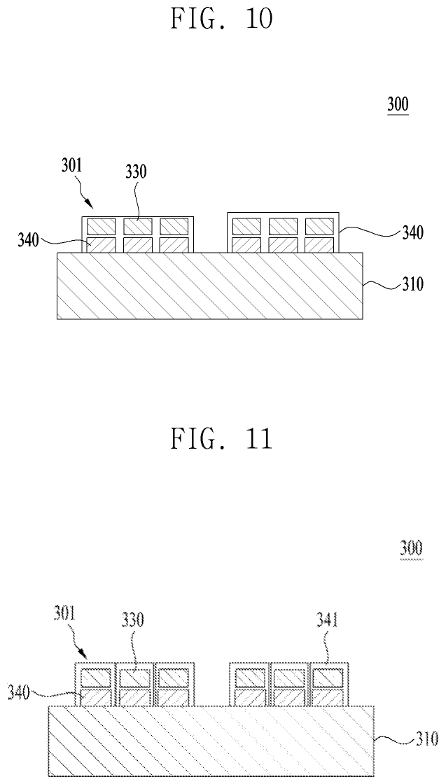

FIGS. 10 and 11 are diagrams illustrating display devices according to embodiments of the present disclosure.

Referring to FIGS. 10 and 11, a display device 300 according to an embodiment of the present disclosure includes a wiring substrate 310, wiring electrodes 320, light emitting devices 330, and adhesive patterns 340.

The wiring substrate 310 may be the substrate 110 shown in FIG. 2 or the substrate 210 shown in FIG. 6. In other words, the wiring substrate 310 may be implemented as a flexible substrate and made of materials such as Polyethylene Naphthalate (PEN) or Polyethylene Terephthalate (PET), which have insulation and flexibility.

At least some of the wiring electrodes 320 are positioned on the wiring substrate 310. FIGS. 10 and 11 illustrate that the wiring electrodes 320 protrude from the surface of the wiring substrate 310. For example, the wiring electrodes 320 may be formed by depositing a metal material on the surface of the wiring substrate 310 and etching the metal material. Alternatively, the wiring electrodes 320 may also be formed by oxidizing certain areas on a separate metal layer and then adhering the metal layer to the wiring substrate 310. However, the present disclosure is not limited thereto. The wiring electrodes 320 may also be positioned inward from the surface of the wiring substrate 310. For example, the wiring electrodes 320 may be formed by etching the surface of the wiring substrate 310, filling the etched part with the metal material, and sintering.

Each of the light emitting devices 330 is electrically connected to a related wiring electrode among the wiring electrodes 320. The light emitting devices 330 may be implemented as LEDs. In particular, each of the light emitting devices 330 may be implemented as a micro LED in a rectangular or square shape with a side length of 100 μm or less, or 80 μm or less, or even 10 μm or less. While FIGS. 10 and 11 illustrate the light emitting devices 330 in a simplified manner, the light emitting devices 330 may have a structure similar to or identical to the above-described semiconductor light emitting devices 150 and 250. For example, the light emitting device 330 may be implemented as the flip-chip type semiconductor light emitting device 150 shown in FIG. 4 or the vertical semiconductor light emitting device 250 shown in FIG. 8.

If the light emitting device 330 is implemented as the flip-chip type semiconductor light emitting device 150 shown in FIG. 4, the light emitting device 330 may include a p-type semiconductor layer, an n-type semiconductor layer, and an active layer formed between the p-type semiconductor layer and the n-type semiconductor layer. In addition, the light emitting device 330 may include p-type and n-type electrodes formed in the p-type semiconductor layer and n-type semiconductor layers, respectively, and arranged to be spaced apart from each other in the horizontal direction. If the light emitting device 330 is implemented as the vertical semiconductor light emitting device 250 shown in FIG. 8, the light emitting device 330 may include a p-type semiconductor layer, an n-type semiconductor layer, and an active layer formed between the p-type semiconductor layer and the n-type semiconductor layer. In addition, the light emitting device 330 may include p-type and n-type electrodes formed in the p-type semiconductor layer and n-type semiconductor layers, respectively, and arranged to face each other with the p-type semiconductor layer, active layer, and n-type semiconductor layer in between. Hereinafter, the p-type electrode and n-type electrode of the light emitting device 330 will be described as a first device electrode and a second device electrode, respectively.

The wiring electrodes 320 may include first wiring electrodes and second wiring electrodes electrically connected to related device electrodes among first device electrodes and second device electrodes of the light emitting devices 330.

If the light emitting devices 330 are implemented in the form of a flip chip, the wiring electrodes 320 may all be positioned on the wiring substrate 310. That is, both the first wiring electrodes and second wiring electrodes may be formed on the wiring substrate 310. For example, if the light emitting devices 330 have a flip-chip form and the display device 100 is implemented to have a structure similar to FIG. 3A, the wiring electrodes 320 in FIGS. 10 and 11 may be interpreted conceptually as including the first electrode 120, second electrode 140, and auxiliary electrode 170 of FIG. 3A. However, the present disclosure is not limited thereto. In contrast to FIG. 3A, the wiring electrodes 310 in FIGS. 10 and 11 may be provided such that the first and second wire electrodes corresponding to the first electrode 120 and the second electrode 140 of FIG. 3A have different heights, and thus, the auxiliary electrode 170 of FIG. 3A may not be separately included.

When the light emitting devices 330 are implemented in a vertical form, the first wiring electrodes among the wiring electrodes 320 may be formed on the wiring substrate 310, while the second wiring electrodes may be formed to face the first wiring electrodes with the light emitting devices 330 in between. However, the present disclosure is not limited thereto. For example, even when the light emitting devices 330 have a vertical form, if the display device 100 is implemented with a structure similar to FIG. 6, the second electrode 240 may not be formed on the top of the n-type electrode such that the second electrode 240 is directly connected to the n-type electrode. That is, if the second electrode 240 is connected to the n-type electrode via protruding connecting electrodes, then both the first wiring electrodes and second wiring electrodes of the wiring electrodes 320 may be formed on the wiring substrate 310. In this case, the wiring electrodes 320 in FIGS. 10 and 11 may be interpreted conceptually as including the first electrode 220, second electrode 240, and connection electrode of FIG. 6.

Continuing to refer to FIGS. 10 and 11, each pixel 301, which is the minimum unit constituting an image, may include three unit pixels, i.e., three light emitting devices 330. However, the display device 100 may adjust the number of light emitting devices 330 included in each pixel 301 as needed. Each light emitting device 330 may implement a color. For example, the light emitting devices 330 may represent the three primary colors of light: red (R), green (G), and blue (B). The display device 300 may adopt various structures to implement the colors corresponding to the light emitting devices 330.

FIG. 10 illustrates an example where all the three light emitting devices 330 constituting one pixel 301 are equipped with the same color LED (for example, blue LED). In this case, different colors (for example, red and green) may be implemented through a phosphor layer (e.g., phosphor layer 180 in FIG. 3b) located on the outer surface of the blue light emitting devices 330.

In contrast, FIG. 11 illustrates an example in which the three light emitting devices 330 constituting one pixel 301 implements R, G, and B, respectively. For example, the light emitting devices 330 in FIG. 11 may implement R, G, and B respectively by adding indium (In) and/or aluminum (Al) to gallium nitride (GaN). Alternatively, the light emitting devices 330 in FIG. 11 may implement R, G, and B respectively by adjusting the particle size of quantum dots.

In contrast to FIG. 10 or 11, among the three light emitting devices 330 constituting one pixel, two light emitting devices may be implemented as blue LEDs and the other may be implemented as a green LED. Then, a red phosphor may be added to one of the two blue LEDs. In addition, the display device 300 may implement pixels in the structure shown in FIG. 5B or 5C.

The light emitting devices 330 emit light when electricity is applied through the wiring electrodes 320. The adhesive patterns 340 adhere the wiring electrodes 320 and the light emitting device 330. In this case, each of the adhesive patterns 340 includes at least one bonding pair of a light emitting device and a wiring electrode, and the adhesive patterns 340 are formed to be spaced apart from each other.

Each adhesive pattern 340 may include the same number of bonding pairs. For example, the adhesive patterns 340 in FIG. 10 may each include three bonding pairs, while adhesive patterns 341 in FIG. 11 may each include one bonding pair.

The adhesive patterns 340 and 341 according to embodiments of the present disclosure possess both adhesive and transfer properties. Specifically, the adhesive patterns 340 and 341 according to the embodiments of the present disclosure have adhesive properties to facilitate mutual adhesion between the light emitting device 330 and wiring electrode 320. Additionally, the adhesive patterns 340 and 341 have transfer properties to prevent issues such as damage to the light emitting device 330 due to laser-induced impacts when a damaged light emitting device 330 is transferred to the wiring electrode 320.

The adhesive patterns 340 according to the embodiments of the present disclosure may be formed using a non-conductive paste (NCP). The NCP according to embodiments of the present disclosure includes a combination of a thermosetting composition and an ultraviolet (UV) B-stage composition. For example, the NCP according to the embodiments of the present disclosure may include the thermosetting composition such as a thermosetting reactive resin, thermosetting hardener, thermosetting catalyst, and epoxy and the UV B-stage composition such as an acrylate, epoxy acrylate, (UV reactive resin or initiator).

Therefore, when the light emitting device 330 is transferred to the wiring electrode 320, the adhesive patterns 340 and 341 according to the embodiments of the present disclosure are cured to a semi-solid state by the UV B-stage composition such that the light emitting device 330 and wiring electrodes 320 are temporality adhered. This enhances the impact resistance of the light emitting device 330 by preventing damage to light emitting device 330 even if a growth substrate 360 is removed by Laser Lift-Off (LLO) technology.

The display device 100 according to the embodiments of the present disclosure does not require the use of a flexible temporary substrate such as polydimethylsiloxane (PDMS) for the light-emitting device 330. In other words, the display device 100 according to the embodiments of the present disclosure may not encounter issues such as damage to the light emitting device 330 even if the light emitting device 33 is directly transferred from the growth substrate 360 to the wiring substrate 310.

The adhesive pattern 340 according to the embodiments of the present disclosure may be cured into a semi-solid state by a curing process for the adhesive pattern 340 when the light emitting device 330 is transferred to the wiring electrode 320. For instance, the curing process may be UV curing (UV B-stage).

The overall content of the UV B-stage composition in the entire NCP may be determined based on a relationship between the following two functions; a function of preventing damage to the light emitting device 330 by absorbing impacts caused by a laser used when the light emitting device 330 is separated from the growth substrate 360; and a function of securing the adhesive strength and conductivity of the adhesive pattern 340 during the bonding process. In other words, the content of the UV B-stage composition in the entire NCP may vary depending on the required degree of semi-solidity (degree of fluidity) of the adhesive pattern 340. For example, if the content of the UV B-stage composition is insufficient, the fluidity of the adhesive pattern 340 may be excessive, resulting in insufficient absorption of the impacts from the laser. If the content of the UV B-stage composition is excessive, the fluidity of the adhesive pattern 340 may be insufficient, leading to insufficient adhesion and an issue of compression of conductive balls.

For example, the content of the UV B-stage composition in the NCP according to the embodiments of the present disclosure may be about 20 to 50%. As observed in the following table, if the content of the UV B-stage composition is less than 20% or exceeds 50%, it may result the following issues: laser damage, conductive ball compression, or adhesive failure.

TABLE 1

| | Embodiment | Embodiment | Embodiment | Comparison | Comparison | Comparison |
|---|---|---|---|---|---|---|
| | 1 | 2 | 3 | example 1 | example 2 | example 3 |
| UV composition | 20 | 35 | 50 | 0 | 10 | 65 |
| content (%) | | | | | | |
| Thermosetting | 80 | 65 | 50 | 100 | 90 | 35 |
| composition content | | | | | | |
| (%) | | | | | | |
| Laser damage | No damage | No damage | No damage | Damage | Damage | No damage |
| conductive ball | Good | Good | Good | Good | Good | Defective |
| compression | | | | | | |
| Adhesive strength | Good | Good | Good | Good | Good | Defective |

In this case, the NCP forming the adhesive patterns 340 according to the embodiments of the present disclosure may have a viscosity ranging from 10,000 to 100,000 centipoise (cps) to ensure molding characteristics for bonding pairs after printing and patterning of the adhesive pattern 340.

The liquid NCP of the adhesive patterns 340 according to the embodiments of the present disclosure undergoes a state transition to a semi-solid state through a semi-curing process at the transfer step. Thus, even if the NCP is used alone, the adhesive patterns 340 may have both adhesive and transfer properties.

Thus, in the display device 100 according to the embodiments of the present disclosure, the process of transferring the light emitting device 330 from the growth substrate 360 onto a temporary substrates such as PDMS is omitted. As a result, it is possible to prevent issues related to the movement of the light emitting device 330 due to a decrease in the number of times of transfer and maintain the positional accuracy on the growth substrate 360, thereby enabling process simplification, cost reduction, and mass production.

As described above, the adhesive patterns 340 and 341 according to the embodiments of the present disclosure may be formed using only the NCP, which is non-conductive, unlike the anisotropic conductive layer used in the display device 100 of FIG. 2. Before patterning the adhesive patterns 340 according to the embodiments of the present disclosure onto the light emitting device 330 or wiring electrodes 320, conductive particles such as conductive balls may be positioned on the growth substrate 360 or wiring substrate 310. However, the present disclosure is not limited thereto, that is, the adhesive patterns 340 according to the embodiments of the present disclosure may also be formed as conductive pastes including conductive balls and so on.

FIGS. 12 and 13 illustrate adhesive patterns according to embodiments of the present disclosure.

As shown in FIGS. 12 and 13, adhesive patterns 340, 342, and 343 may be patterned such that the adhesive patterns 340, 342, and 343 encapsulate light emitting devices 330, i.e., encase the light emitting devices 330 as a whole and form a spacing from other adhesive patterns. When the adhesive patterns 340, 342, and 343 are patterned onto the light emitting devices 330, the adhesive patterns 340, 342, and 343 may be patterned to encase wiring electrodes 320, which form bonding pairs during a subsequent transfer processes. Therefore, a sufficient amount of NCP capable of encasing one or more bonding pairs included in one adhesive pattern 340 or 342 may be used for each adhesive pattern 340 or 342.

The adhesive patterns 340, 342, and 343 may not be limited to the embodiments of FIGS. 12 and 13. That is, the adhesive patterns 340, 342, and 343 may be patterned in various forms. For example, the number of bonding pairs included in the adhesive patterns 340, 342, and 343 may vary depending on the color implementation structure of the light emitting devices 330. As described, three light emitting devices 330 constituting one pixel may be all the same blue LED or separately implement R, G, and B. For the former, the adhesive patterns 340 may be implemented as shown in the embodiment of FIG. 12, while for the latter, the adhesive patterns 342 and 343 may implemented as shown in the embodiment of FIG. 13. Thus, due to the inclusion of a light emitting device transferred at an arbitrary time point and a light emitting device not transferred in different adhesive patterns, the conditions required to separate the light emitting device 330 from the growth substrate 360 (in FIG. 12) during the transfer are relaxed, thereby mitigating the impacts on the light emitting device 330.

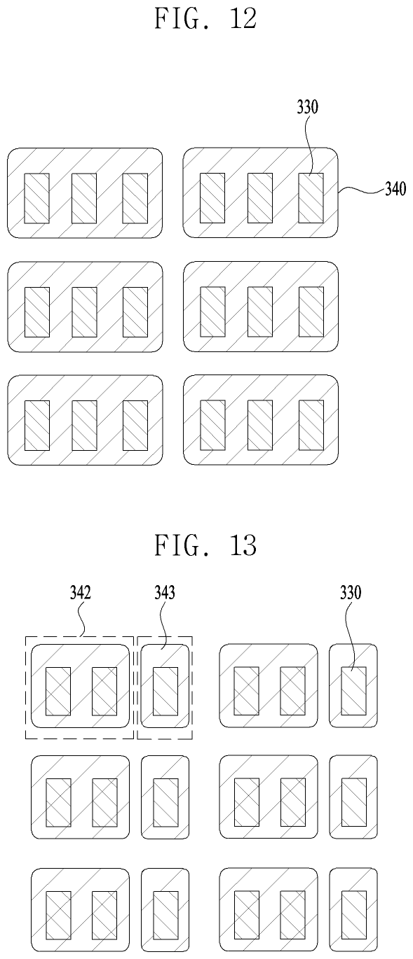

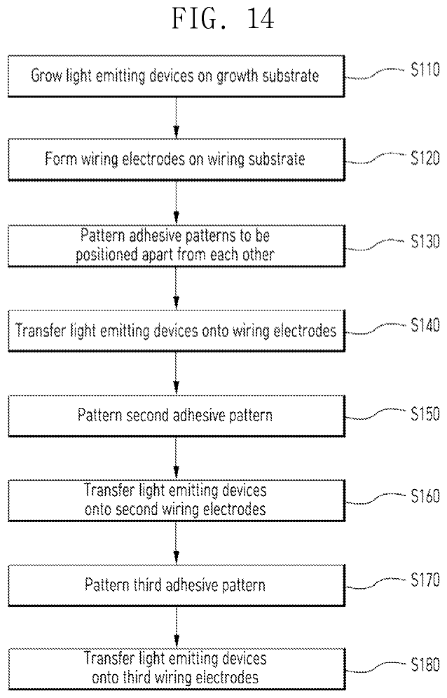

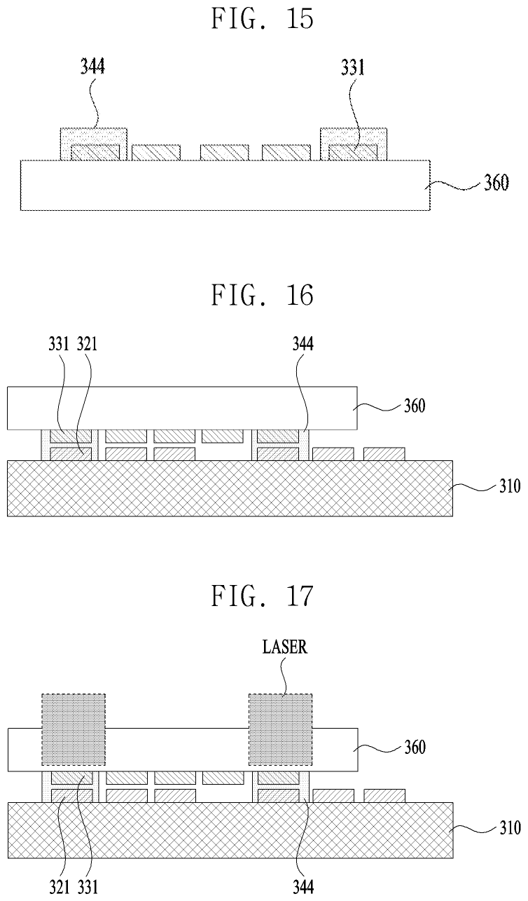

FIG. 14 is a flowchart illustrating a method of manufacturing a display device based on light emitting devices according to an embodiment of the present disclosure. FIGS. 15 to 24 are cross-sectional views illustrating steps of the method of manufacturing a display device based on light emitting devices according to an embodiment of the present disclosure.

Hereinafter, a manufacturing method applicable to a display device 300 according to embodiments of the present disclosure will be described with reference to FIGS. 14 to 24. Each manufacturing step will be explained in conjunction with the related drawing in addition with FIG. 14.

Referring to FIG. 14, a step S110 of preparing a growth substrate 360 on which light emitting devices 331 are formed may be performed (refer to the state of FIG. 15 for reference numerals).

The light emitting devices 331 may emit light of the same color and be grown on the growth substrate 360. For example, the light emitting device 331 may be a blue light emitting device emitting blue light.

The step S110 of preparing the growth substrate 360 on which the light emitting devices 331 are formed may include a process of growing the light emitting devices 331 on the growth substrate 360.

The process of growing the light emitting devices 331 may involve sequentially forming semiconductor layers for light emitting device formation on the growth substrate 360 and etching the layers to separate into individual devices.

The step S110 of growing the light emitting devices 330 on the growth substrate 360 may implement chip-shaped light emitting devices 330 by growing semiconductor thin films on the growth substrate 360 made of a sapphire or silicon material.

For example, if the growth substrate 360 is made of a sapphire material. GaN light emitting devices 330 may be grown by utilizing various sources at temperatures exceeding 550° C., for a runtime of 6 to 8 hours.

When the light emitting devices 330 are formed at the wafer level, the light emitting devices 330 may be designed to be aligned with the spacing and size used in a display device 100, i.e., the spacing or position of wiring electrodes 320. This may enhance the manufacturability of the display device 100. The grown light emitting devices 330 may be either flip chip micro LEDs or vertical micro LEDs as described earlier.

Referring to FIG. 14, a step S120 of preparing a wiring substrate 310 equipped with wiring electrodes 321 may be performed (refer to the state of FIG. 16 for reference numerals).

The step S120 of forming the wiring electrodes 321 on the wiring substrate 310 may be performed by depositing a metal material onto the surface of the wiring substrate 310 and performing etching thereon as described above, but the present disclosure is not limited thereto.

To implement the display device 300 to be flexible, the wiring substrate 310 may include materials such as PI. If the display device 300 has the structure shown in FIG. 2, first wiring electrodes and second wiring electrodes among the wiring electrodes 321 may be arranged in mutually orthogonal directions.

The step S110 of preparing the growth substrate 360 on which the light emitting devices 331 are formed and the step S120 of forming the wiring electrodes 321 on the wiring substrate 310 may be performed independently of each other. In other words, FIG. 14 illustrates an example where the two steps S110 and S120 are performed sequentially, but this is merely illustrative.

Referring to FIGS. 14 and 15, a step S130 of forming (patterning) adhesive patterns to be positioned apart from each other may be performed.

The adhesive patterns may be formed on at least one of first wiring electrodes among the wiring electrodes and first light emitting devices among the light emitting devices (first adhesive pattern). In other words, a first adhesive pattern 344 may be formed on a first wiring electrode 321 or a first light emitting device 331, and in some cases, the first adhesive pattern 344 may be formed on both the first wiring electrode 321 and the first light emitting device 331. For example, when an adhesive pattern is formed on at least three wiring electrodes constituting one pixel, the adhesive pattern may be formed only on the wiring electrodes. Hereinafter, an example of forming an adhesive pattern for each light emitting device that emits one color on one pixel will be described.

With reference to FIG. 15, a case where multiple blue light emitting devices are formed on the growth substrate 360 will be described. The first adhesive pattern 344 may be formed on the selected first light emitting device 331 such that at least one blue light emitting device among the multiple blue light emitting devices is assembled to each pixel. In addition, although not shown, the first adhesive pattern 344 may also be formed on the selected first wiring electrode 321 such that at least one blue light emitting device is assembled to each pixel.

A step S130 of patterning the first adhesive patterns 344 may be performed by performing dispensing, pattern printing, or inkjet printing of an adhesive material. An NCP may be used as the adhesive material. The specific composition and characteristics of the NCP forming the adhesive pattern 344 are the same as described above.

An additional step of placing conductive particles on the wiring substrate 310 or the growth substrate 360 may be further included before executing the step S130 of patterning the first adhesive patterns 344.

Referring to FIGS. 14 and 16, a step S140 of transferring the first light emitting device 331 onto the first wiring electrode 321 such that the first light emitting device 331 among the light emitting devices is adhered to the first wiring electrode 321 by the first adhesive pattern 344 may be performed.

In other words, after patterning the first adhesive patterns 344 on the growth substrate 360 or the wiring substrate 310, the first light emitting devices 331 may be transferred onto the first wiring electrodes 321 (S140). By performing a single transfer step, coupling pairs of the first light emitting devices 331 and the first wiring electrodes 321 may be formed due to the first adhesive patterns 344, which are islanded and possess both adhesive and transfer properties.

Concurrently with or immediately after the transfer step, the state of the first adhesive patterns 344 composed of the liquid NCP may transition into a semi-solid state through a semi-curing process. For example, the semi-curing process may be a UV semi-curing process (UV B-stage). Through the UV semi-curing process, a UV B-stage composition among substances composing the NCP reacts, causing the first adhesive patterns 344 to have the semi-solid state. The first light emitting device 331 and first wiring electrode 321 corresponding to a bonding pair (BPAR) may be adhered. The above operation may also be applied similarly to a second adhesive pattern 345 or 346 and a third adhesive pattern 347, which will be described later.

Referring to FIG. 17, after transferring the first light emitting devices 331 onto the first wiring electrodes 321 (S140), LLO may be performed on the growth substrate 360. In other words, a laser may be irradiated onto the growth substrate 360 to separate the first light emitting devices 331 from the growth substrate 360.

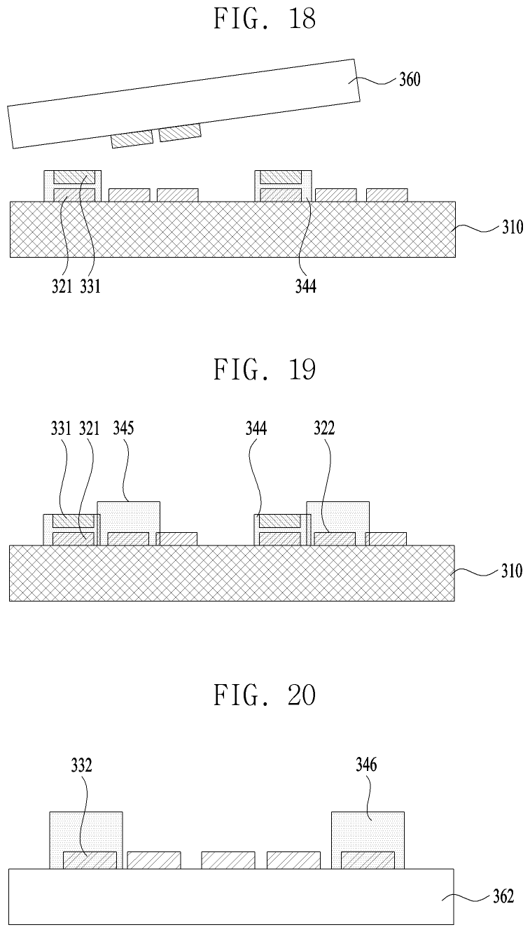

Accordingly, as shown in FIG. 18, the first light emitting devices 331 may be detached from the growth substrate 360 and transferred onto the first wiring electrodes 321.

When the first light emitting devices 331 are detached from the growth substrate 360, the adhesive patterns 344 transition into the semi-solid state, thereby mitigating the impacts on the first light emitting devices 331 caused by the laser. In addition, the islanded (molded) adhesive patterns 344 maintain gap-filling characteristics or bonding properties because sufficient space for the adhesive material to flow is secured due to a gap between the adhesive patterns 344. Thus, both yield and performance may be enhanced even for large-area processes.

Referring to FIGS. 19 and 20 together with FIG. 14, a step S150 of forming (patterning) a second adhesive pattern 345 or 356 with a different height from the first adhesive pattern 344 on at least one of a second wiring electrode 322 adjacent to the first wiring electrode 321 among the wiring electrodes and a second light emitting device 332 adjacent to the first light emitting device 331 among the light emitting devices may be performed.

As illustrated in FIG. 19, the second adhesive pattern 345 may be formed on the second wiring electrode 322 adjacent to the first wiring electrode 321. Additionally/alternatively, as illustrated in FIG. 20, the second adhesive pattern 346 may be formed on the second light emitting device 332. In some cases, the second adhesive patterns 345 and 346 may be formed on both the second wiring electrode 322 and the second light emitting device 332.

Referring to FIG. 19, the height of the second adhesive pattern 345 may differ from the height of the first adhesive pattern 344. Specifically, the height of the second adhesive pattern 345 may be greater than the height of the first adhesive pattern 344.

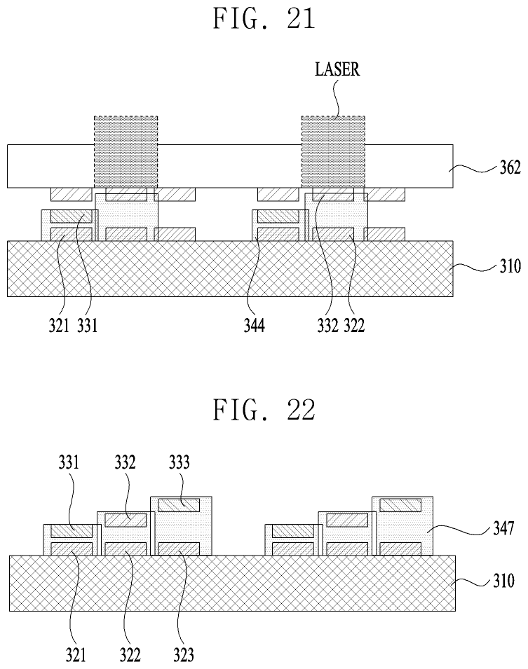

Referring to FIGS. 14 and 21, a step S160 of transferring the second light emitting device 332 among the light emitting devices onto the second wiring electrode 322 may be performed such that the second light emitting device 332 is adhered by the second adhesive pattern 345 or 346 to the second wiring electrode 322.

That is, after patterning the second adhesive patterns 346 on the growth substrate 362 as shown in FIG. 20 or patterning the second adhesive patterns 345 on the wiring substrate 310 as shown in FIG. 19, the second light emitting devices 332 may be transferred onto the second wiring electrodes 322 (S160). By performing a single transfer step, coupling pairs of the second light emitting device 332 and the second wiring electrode 322 may be formed due to the second adhesive patterns 345 and 346, which are islanded and possess both adhesive and transfer properties.

Concurrently with or immediately after the transfer step, the state of the second adhesive patterns 345 and 346 composed of the liquid NCP may transition into a semi-solid state through a semi-curing process. For example, the semi-curing process may be a UV semi-curing process (UV B-stage).

Referring to FIG. 21, after transferring the second light emitting device 332 onto the second wiring electrodes 322 (S160), LLO may be performed on the growth substrate 360. In other words, a laser may be irradiated onto a portion of the growth substrate 360 where the second light emitting device 332 is located, thereby separating the second light emitting devices 332 from the growth substrate 360.

Accordingly, as shown in FIG. 21, the second light emitting devices 332 may be detached from the growth substrate 360 and transferred onto the second wiring electrodes 322. For example, the second light emitting devices 332 may be green light emitting devices that emit green light.

Thereafter, the same process may be performed for a third light emitting device 333. The third light emitting device 333 may be a red light emitting device emitting red light.

The third adhesive pattern 347 may be formed on a third wiring electrode 323 adjacent to the second wiring electrode 322. Additionally/alternatively, the third adhesive pattern 347 may be formed on the third light emitting device 333. In some cases, the third adhesive pattern 347 may be formed on both the third wiring electrode 323 and the third light emitting device 333.

The height of the third adhesive pattern 347 may differ from the height of the second adhesive pattern 345. Specifically, the height of the third adhesive pattern 347 may be greater than the height of the second adhesive pattern 345.

Then, a step of transferring the third light emitting device 333 onto the third wiring electrode 323 such that the third light emitting device 333 among the light emitting devices is adhered by the third adhesive pattern 347 may result in a state shown in FIG. 22.

If the height of the second adhesive pattern 345 or 346 is equal to the height of the first adhesive pattern 344, the second light emitting devices 332 may experience interference with the first light emitting devices 331, which is transferred before, resulting in the second light emitting devices 332 not making substantial contact with the second wiring electrodes 322. Therefore, the second light emitting devices 332 may not be transferred onto the second wiring electrodes 322.

However, due to the height difference between the first adhesive pattern 344 and the second adhesive pattern 345 or 346, interference may not occur, and thus the second light emitting devices 332 may be readily transferred onto the second wiring electrodes 322.

In this way, according to embodiments of the present disclosure, adhesive patterns may be applied multiple times to achieve sufficient adhesive performance. In addition, differences in height between the adhesive patterns may be obtained by varying the thickness of each adhesive pattern during the transfer process, thereby preventing transfer failure due to interference.

In this case, for example, the thickness of the first adhesive pattern 344 for transferring the first light emitting device 331 may range from 1 to 10 μm, which may have a difference of 10 to 30 μm compared to the second adhesive pattern 345 for transferring the second light emitting device 332. In addition, for example, the second adhesive pattern 345 for transferring the second light emitting device 332 may have a difference of 10 to 30 μm compared to the third adhesive pattern 347 for transferring the third light emitting device 333.

The adhesive patterns in each step, that is, the first adhesive pattern 344, second adhesive pattern 345, and third adhesive pattern 347 include UV B-stage. This allows the adhesive pattern to maintain the form thereof upon additional application of the adhesive pattern as the adhesive pattern transforms from a liquid state to a semi-solid state, thereby reducing the failure rate during the LLO process and improving yield by providing high adhesive strength and high elasticity.

As described above, the transfer of the light emitting devices 331, 332, and 333 onto the related wiring electrodes 321, 322, and 323 may be repeated by the number to colors implemented by the light emitting devices 331, 332, and 333. By doing so, the transfer for each pixel may be completed.

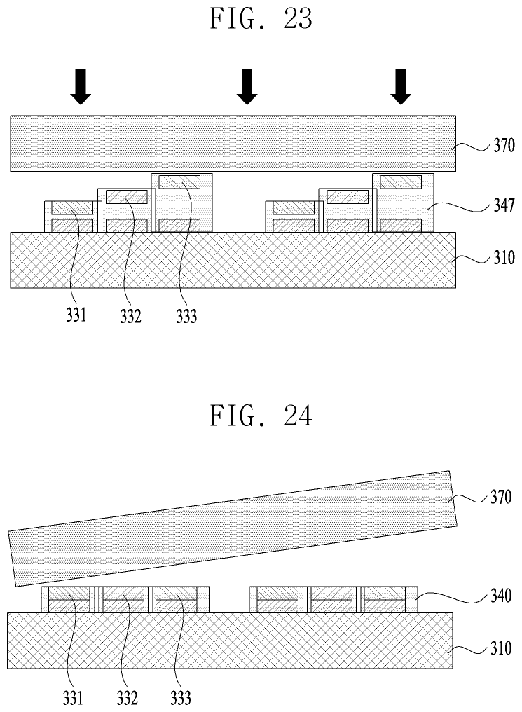

Referring to FIG. 23, after completing the transfer step S160 for each pixel, bonding pairs may be thermally compressed and bonded. The thermal compression bonding process is carried out with a bonding substrate 370 temporarily provided to protect the bonding pairs during the corresponding process. After completion of the thermal compression bonding process, the bonding substrate 370 may be removed (FIG. 24).

During the thermal compressing bonding process, the first and second adhesive patterns 344 and 345, which have different heights, may be pressed such that the first and second adhesive patterns 344 and 345 have the same height as illustrated in FIG. 24. In addition, the heights of the first to third adhesive patterns 344, 345, and 347 may all become the same.

After completion of all the processes, the structure shown in FIG. 10 may be achieved.

In the method of manufacturing a display device according to the embodiments of the present disclosure, light emitting devices representing different colors are individually transferred, and then bonding is simultaneously performed as described above, thereby preventing illumination defects caused by interference and collision that may occur during sequential bonding.

The features, structures, effects, and so on described above in the embodiments are included in at least one embodiment of the present disclosure and are not necessarily limited to only one embodiment. In addition, features, structures, effects, and so on exemplified in each embodiment may be combined with or modified to other embodiments by those skilled in the art to which the embodiments belong. Therefore, it should be interpreted that such combinations and modifications are included within the scope of the present disclosure.

While the present disclosure has been described with reference to exemplary embodiments, it should be noted that the embodiments are merely examples and do not limit the scope of the present disclosure. It will be appreciated by those skilled in the art to which the present disclosure belongs that various modifications and applications beyond those illustrated herein are possible within the scope of the essential characteristics of the embodiments. For example, each component described in the embodiments may be modified in various ways. Differences related to the modifications and applications should be interpreted as being included within the scope of the present disclosure as defined in the appended claims.

### INDUSTRIAL APPLICABILITY

The present disclosure provides a display device based on semiconductor light emitting devices such as micro light emitting diodes (LEDs) and method for manufacturing the same.

1. A method of manufacturing a display device based on a light emitting device, the method comprising:
preparing a growth substrate on which light emitting devices are formed;
preparing a wiring substrate including wiring electrodes;
forming a first adhesive pattern on at least one of a first wiring electrode among the wiring electrodes and a first light emitting device among the light emitting devices;
transferring the first light emitting device onto the first wiring electrode such that the first light emitting device among the light emitting devices is adhered to the first wiring electrode by the first adhesive pattern;
forming a second adhesive pattern on at least one of a second wiring electrode adjacent to the first wiring electrode among the wiring electrodes and a second light emitting device adjacent to the first light emitting device among the light emitting devices, wherein a height of the first adhesive pattern is different from a height of the second adhesive pattern; and
transferring the second light emitting device onto the second wiring electrode such that the second light emitting device among the light emitting devices is adhered to the second wiring electrode by the second adhesive pattern.

2. The method of claim 1, wherein each of the first and second adhesive patterns has adhesive properties for adhering the wiring electrodes to the light emitting devices and transfer properties required for transferring the light emitting devices onto the wiring electrodes.

3. The method of claim 1, wherein the height of the second adhesive pattern is greater than the height of the first adhesive pattern.

4. The method of claim 1, further comprising:
forming a third adhesive pattern on at least one of a third wiring electrode adjacent to the second wiring electrode among the wiring electrodes and a third light emitting device adjacent to the second light emitting device among the light emitting devices, wherein a height of the second adhesive pattern is different from a height of the third adhesive pattern; and
transferring the third light emitting device onto the third wiring electrode such that the third light emitting device among the light emitting devices is adhered to the third wiring electrode by the third adhesive pattern.

5. The method of claim 4, wherein the height of the third adhesive pattern is greater than the height of the second adhesive pattern.

6. The method of claim 1, wherein forming the first and second adhesive patterns comprises performing dispensing, pattern printing, or inkjet printing of adhesive materials onto the wiring substrate.

7. The method of claim 1, further comprising transitioning states of the first and second adhesive patterns to a semi-solid state.

8. The method of claim 7, wherein transitioning the states of the first and second adhesive patterns to the semi-solid state comprises an ultraviolet (UV) semi-curing (UV B-stage) process.

9. The method of claim 7, further comprising performing Laser Lift-Off (LLO) on the growth substrate after transitioning the states of the adhesive patterns to the semi-solid state.

10. The method of claim 1, further comprising performing thermal compression bonding on the first and second light emitting devices simultaneously.

11. The method of claim 10, wherein performing the thermal compression bonding comprises applying pressure such that the first and second adhesive patterns with different heights have a same height.

12. The method of claim 1, wherein each of the first and second adhesive patterns is made of a non-conductive paste (NCP) capable of a state transition to a semi-solid state.

13. The method of claim 12, wherein the NCP includes an ultraviolet (UV) B-Stage composition and a thermosetting composition.

14. The method of claim 13, wherein a content of the UV B-Stage composition in the NCP ranges from 20% to 50%.

15. The method of claim 12, wherein a viscosity of the NCP ranges from 10,000 to 100,000 centipoise (cps).

16. The method of claim 12, wherein the NCP includes at least one of an acrylate and an epoxy acrylate.

17. The method of claim 1, wherein a curvature of an adhesive pattern corresponding to bonding pairs constituting one pixel among bonding pairs is constant.

18. A display device based on a light emitting device, the display device comprising:
a wiring substrate;
wiring electrodes positioned on the wiring substrate and comprising a first wiring electrode, a second wiring electrode, and a third wiring electrode that form a unit pixel;
light emitting devices comprising a first light emitting device, a second light emitting device, and a third light emitting device respectively and electrically connected to the first wiring electrode, the second wiring electrode, and the third wiring electrode that form the unit pixel; and
adhesive patterns comprising a first adhesive pattern, a second adhesive pattern, and a third adhesive pattern formed independently of each other and having adhesive properties for respectively adhering the first wiring electrode to the first light emitting device, the second wiring electrode to the second light emitting device, and the third wiring electrode to the third light emitting device and transfer properties required for transferring the light emitting devices to the wiring electrodes.

19. The display device of claim 18, wherein after thermal compression bonding, the first adhesive pattern, the second adhesive pattern, and the third adhesive pattern with different heights have a same height.

20. The display device of claim 18, wherein each of the first adhesive pattern, the second adhesive pattern, and the third adhesive pattern is made of a non-conductive paste (NCP) capable of a state transition to a semi-solid state, and
wherein the NCP includes an ultraviolet (UV) B-Stage composition and a thermosetting composition.
